(19) United States
(12) Patent Application Publication
(10) Pub. No.: US 2011/0241798 A1
(43) Pub. Date: Oct. 6, 2011

(54) RESONATOR FOR COMMUNICATION SYSTEM AND FILTER USING THE SAME

(75) Inventors: Ju-Yeon HONG, Daejeon (KR); Jeong-Ho Ju, Seoul (KR); Dong-Ho Kim, Daejeon (KR); Young-Jun Chong, Daejeon (KR); Wangjoo Lee, Daejeon (KR); Jae-Ick Choi, Daejeon (KR)

(73) Assignee: ELECTRONICS AND TELECOMMUNICATIONS RESEARCH INSTITUTE, Daejeon (KR)

(21) Appl. No.: 13/070,537

(22) Filed: Mar. 24, 2011

(30) Foreign Application Priority Data
Mar. 31, 2010 (KR) 10-2010-0029416

(51) Int. Cl. H03H 7/01

(52) U.S. Cl. 333/175

(57) ABSTRACT

Provided are a resonator and a filter performing a filtering operation by using the resonator. The filter includes a first resonation unit connected in series to an input terminal and having a first resonant frequency, a filtering unit connected in series to the first resonation unit to filter a signal inputted through the input terminal, a second resonation unit connected in series between the filtering unit and an output terminal and having a second resonant frequency, a first zero-order resonation unit connected in parallel to a connection terminal between the input terminal and the first resonation unit and having a first zero-order resonant frequency equal to the first resonant frequency, and a second zero-order resonation unit connected in parallel to a connection terminal between the output terminal and the second resonation unit and having a second zero-order resonant frequency equal to the second resonant frequency.

### CROSS-REFERENCE TO RELATED APPLICATIONS

The present application claims priority of Korean Patent Application No. 10-2010-0029416, filed on Mar. 31, 2010, which is incorporated herein by reference in its entirety.

### BACKGROUND OF THE INVENTION

1. Field of the Invention

Exemplary embodiments of the present invention relate to communication systems; and, more particularly, to a resonator for improving the filtering RF spectrum characteristics of a filter filtering a signal according to a predetermined frequency band in a communication system, and a filter performing a filtering operation by using the resonator.

2. Description of Related Art

In communication systems, communication is performed by transmitting/receiving radio frequency (RF) signals, and it is necessary to filter the RF signals according to a predetermined frequency band in order to perform the communication. The filter is used to pass a signal of a specific frequency band among input frequency signals. The band-pass frequency of an RF filter is determined by the inductance component and the capacitance component of the filter, and the band-pass frequency of the filter is controlled to filter signals of a desired frequency band to communicate the signals.

Meanwhile, in communication systems, the filtering characteristics of a filter are important for more accurate communication of signals. In particular, extensive research is being conducted on a filter for improving the filtering performance of signals of other frequency bands than a given frequency band without RF spectrum degradation in a broadband communication system. That is, a filter capable of improving the filtering performance without RF spectrum degradation is required in communication systems.

### SUMMARY OF THE INVENTION

An embodiment of the present invention is directed to a resonator for improving the filtering performance without RF spectrum degradation in a communication system, and a filter using the resonator.

Another embodiment of the present invention is directed to a resonator for performing an impedance matching operation in a broadband communication system, and a filter for improving the filtering performance by using the resonator.

Another embodiment of the present invention is directed to a resonator capable of being easily coupled with a filter (e.g., an elliptic filter, a Chebyshev filter, and a Butterworth filter) without RF spectrum degradation, and a filter for improving the filtering performance by using the resonator.

Other objects and advantages of the present invention can be understood by the following description, and become apparent with reference to the embodiments of the present invention. Also, it is obvious to those skilled in the art to which the present invention pertains that the objects and advantages of the present invention can be realized by the means as claimed and combinations thereof.

In accordance with an embodiment of the present invention, a resonator for a communication system includes: a first zero-order resonation unit connected in parallel to an input terminal of a filter and having a zero-order resonant frequency equal to a resonant frequency of a first resonation unit of the filter connected in series to the input terminal; and a second zero-order resonation unit connected in parallel to an output terminal of the filter and having a zero-order resonant frequency equal to a resonant frequency of a second resonation unit of the filter connected in series to the output terminal, wherein the first zero-order resonation unit includes a first inductor and a first capacitor connected in parallel between a ground terminal and a connection terminal between the input terminal and the first resonation unit; and the second zero-order resonation unit includes a second inductor and a second capacitor connected in parallel between the ground terminal and a connection terminal between the output terminal and the second resonation unit.

In accordance with another embodiment of the present invention, a filter for a communication system includes: a first resonation unit connected in series to an input terminal and having a first resonant frequency; a filtering unit connected in series to the first resonation unit to filter a signal inputted through the input terminal; a second resonation unit connected in series between the filtering unit and an output terminal and having a second resonant frequency; a first zero-order resonation unit connected in parallel to a connection terminal between the input terminal and the first resonation unit and having a first zero-order resonant frequency equal to the first resonant frequency; and a second zero-order resonation unit connected in parallel to a connection terminal between the output terminal and the second resonation unit and having a second zero-order resonant frequency equal to the second resonant frequency, wherein the first zero-order resonation unit includes a first inductor and a first capacitor connected in parallel between a ground terminal and the connection terminal between the input terminal and the first resonation unit; the second zero-order resonation unit includes a second inductor and a second capacitor connected in parallel between the ground terminal and the connection terminal between the output terminal and the second resonation unit; the first resonation unit includes a third inductor and a third capacitor connected in series to the input terminal; and the second resonation unit includes a fourth capacitor and a fourth inductor connected in series to the output terminal.

In accordance with another embodiment of the present invention, a resonator for a communication system includes: a first zero-order resonation unit connected in series to an input terminal of a filter and having a zero-order resonant frequency equal to a resonant frequency of a first resonation unit of the filter connected in parallel to the input terminal; and a second zero-order resonation unit connected in series to an output terminal of the filter and having a zero-order resonant frequency equal to a resonant frequency of a second resonation unit of the filter connected in parallel to the output terminal, wherein the first zero-order resonation unit includes a first inductor and a first capacitor connected in parallel between the input terminal and the first resonation unit; and the second zero-order resonation unit includes a second inductor and a second capacitor connected in parallel between the output terminal and the second resonation unit.

In accordance with another embodiment of the present invention, a filter for a communication system includes: a first resonation unit connected in parallel to an input terminal and having a first resonant frequency; a filtering unit connected in series to the first resonation unit to filter a signal inputted through the input terminal; a second resonation unit connected in parallel between the filtering unit and an output terminal and having a second resonant frequency; a first zero-order resonation unit connected in series between the input terminal and the first resonation unit and having a first zero-order resonant frequency equal to the first resonant frequency; and a second zero-order resonation unit connected in series between the output terminal and the second resonation unit and having a second zero-order resonant frequency equal to the second resonant frequency, wherein the first zero-order resonation unit includes a first inductor and a first capacitor connected in parallel between a ground terminal and the connection terminal between the input terminal and the first resonation unit; the second zero-order resonation unit includes a second inductor and a second capacitor connected in parallel between the ground terminal and the connection terminal between the output terminal and the second resonation unit; the first resonation unit includes a third inductor and a third capacitor connected in series to the input terminal; and the second resonation unit includes a fourth capacitor and a fourth inductor connected in series to the output terminal.

### BRIEF DESCRIPTION OF THE DRAWINGS

FIG. 1 is a diagram illustrating a resonator and a filter using the resonator for a communication system in accordance with an exemplary embodiment of the present invention.

FIGS. 2A and 2B are graphs illustrating the band-pass characteristics of a filter in accordance with an exemplary embodiment of the present invention.

FIG. 3 is a graph illustrating the transmission characteristics of a filter in accordance with an exemplary embodiment of the present invention.

FIGS. 4A and 4B are graphs illustrating the phase characteristics of a filter in accordance with an exemplary embodiment of the present invention.

FIG. 5 is a graph illustrating the ripple characteristics of a filter in accordance with an exemplary embodiment of the present invention.

FIGS. 6A and 6B are graphs illustrating a group delay of a filter in accordance with an exemplary embodiment of the present invention.

FIGS. 7A and 7B are graphs illustrating a reflection coefficient of a filter in accordance with an exemplary embodiment of the present invention.

### DESCRIPTION OF SPECIFIC EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The present invention provides a resonator for improving the filtering performance without RF spectrum degradation in a communication system, and a filter using the resonator. Exemplary embodiments of the present invention provide a filter for filtering an RF signal according to a frequency spectrum, and a resonator for improving the filtering performance through impedance matching without degrading the RF spectrum characteristics of the filter by being coupled with the filter.

In an exemplary embodiment of the present invention, a filter is implemented by coupling a resonator with a metamaterial zero-order resonation unit to a filter (e.g., an elliptic filter, a Chebyshev filter, and a Butterworth filter) including a resonation unit. Herein, the resonator and the filter are coupled together by matching the zero-order resonant frequency and the bandwidth to the band-pass characteristics of an elliptic filter by using the frequency dispersion characteristics of the zero-order resonation unit. The filter coupled with the resonator improves the RF spectrum characteristics (e.g., the band cut-off characteristics) without degrading the band-pass characteristics of a filter (e.g., an elliptic filter, a Chebyshev filter, and a Butterworth filter).

Also, in an exemplary embodiment of the present invention, the resonation units of a filter including a plurality of resonation units are divided into minimum units. A metamaterial resonation unit with zero-order resonance is provided at the resonation unit connected to an input/output port that is an input/output terminal. The metamaterial resonation unit is used to improve the band cut-off characteristics without degrading the RF spectrum characteristics of the filter. Herein, the metamaterial resonation unit is a zero-order resonator without a band gap. The metamaterial resonation unit does not have a band gap because the resonant frequency of the resonation unit connected to the input/output port of the filter is equal to the zero-order resonant frequency of the zero-order resonator. Herein, the frequency bandwidth thereof is suitably controlled to perform an impedance matching operation in a broadband system and improve the band cut-off characteristics.

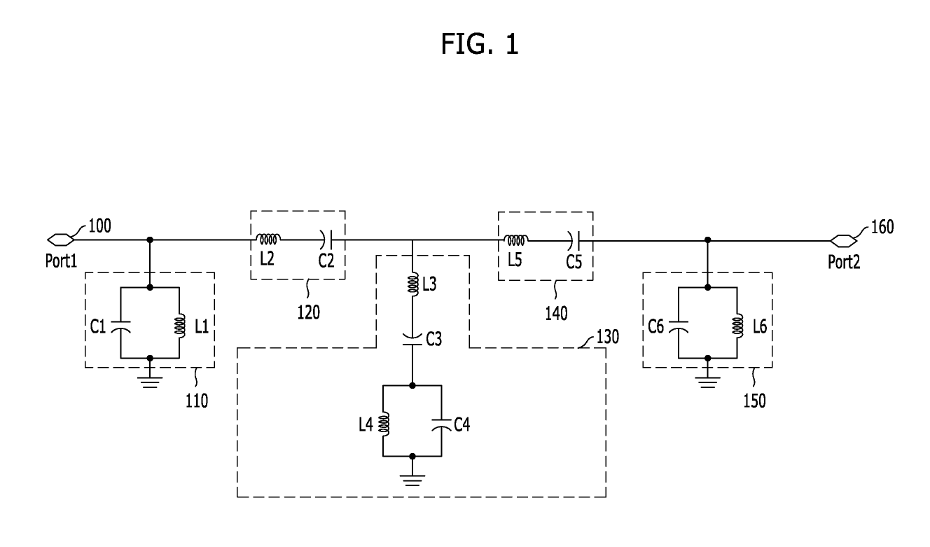

Also, in an exemplary embodiment of the present invention, a resonation unit having the same zero-order resonant frequency as a resonation unit connected to an input/output port is coupled with a filter in order to improve the band cut-off characteristics around a transmission zero, thereby significantly improving the band cut-off characteristics by a gradient variation. Herein, the frequency dispersion characteristics are used to control the bandwidth and control the zero-order resonant frequency, and the transmission characteristics of a resonation unit coupled with a filter (i.e., a zero-order resonation unit) are matched to the transmission characteristics of the filter to couple the zero-order resonation unit and the filter together. That is, the filter includes a zero-order resonation unit having a zero-order resonant frequency. Herein, the resonant frequency of the resonation unit connected to the input/output terminal of the filter is equal to the zero-order resonant frequency of the zero-order resonation unit, and the zero-order resonant frequency bandwidth of the zero-order resonation unit is adapted to the bandwidth of the filter. Hereinafter, a resonator for a communication system and a filter using the same in accordance with an exemplary embodiment of the present invention will be described in detail with reference to FIG. 1.

FIG. 1 is a diagram illustrating a resonator for a communication system and a filter using the same in accordance with an exemplary embodiment of the present invention.

Referring to FIG. 1, the filter includes: a first resonator unit 120 and a second resonation unit 140 connected in series to a first port 100 (i.e., an input terminal) and a second port 160 (i.e., an output terminal); a filtering unit 130 connected between the first resonation unit 120 and the second resonation unit 140; a first zero-order resonation unit 110 provided between the first port 100 and the first resonation unit 120; and a second zero-order resonation unit 150 provided between the second port 160 and the second resonation unit 140. Herein, the first zero-order resonation unit 110 is a metamaterial resonator having a zero-order frequency equal to the resonant frequency of the first resonation unit 120. The second zero-order resonation unit 150 is a metamaterial resonator having a zero-order frequency equal to the resonant frequency of the second resonation unit 140.

In the filter in accordance with an exemplary embodiment of the present invention, the first zero-order resonation unit 110 and the second zero-order resonation unit 150 are coupled with a filter (e.g., an elliptic filter, a Chebyshev filter, and a Butterworth filter) implemented by the first resonation unit 120, the second resonation unit 140 and the filtering unit 130, in order to improve the band cut-off characteristics without degrading the RF spectrum characteristics of the filter. That is, in the filter in accordance with an exemplary embodiment of the present invention, the filter including the first resonation unit 120, the second resonation unit 140 and the filtering unit 130 includes the first zero-order resonation unit 110 and the second zero-order resonation unit 150 at the input/output terminal thereof. Herein, the impedance matching in a broadband system is formed by the bandwidth of the first zero-order resonation unit 110 and the second zero-order resonation unit 150, thereby improving the band cut-off characteristics of the filter without degrading the RF spectrum transmission characteristics of the filter.

In an exemplary embodiment of the present invention, the first resonation unit 120 and the second resonation unit 140 are connected in series between the input/output terminals, and the filtering unit 130 is connected between a ground terminal and a connection terminal between the first resonation unit 120 and the second resonation unit 140. In another exemplary embodiment of the present invention, if the first resonation unit 120 and the second resonation unit 140 are connected in parallel between the input/output terminals, the first zero-order resonation unit 110 and the second zero-order resonation unit 150 are connected in series. That is, if the first resonation unit 120 and the second resonation unit 140 are connected between the input/output terminals to connect the first zero-order resonation unit 110 and the second zero-order resonation unit 150, i.e., if the first resonation unit 120 and the second resonation unit 140 are connected in series, the first zero-order resonation unit 110 and the second zero-order resonation unit 150 are connected in parallel to couple the filter and the resonator together. If the first resonation unit 120 and the second resonation unit 140 are connected in parallel, the first zero-order resonation unit 110 and the second zero-order resonation unit 150 are connected in series to couple the filter and the resonator together. The present invention controls the frequency bandwidth between the filter and the resonator to improve the band cut-off characteristics without degrading the characteristics of the filter.

The first resonation unit 120 includes a second inductor L2 and a second capacitor C2 connected in series to the first port 100. The first zero-order resonation unit 110 includes a first capacitor C1 and a first inductor L1 connected between the ground terminal and a connection terminal between the first port 100 and the first resonation unit 120 (i.e., connected in parallel to the first port 100 and the first resonation unit 120). If the first resonation unit 120 is connected in parallel to the first port 100, the second inductor L2 and the second capacitor C2 are connected in series between the first zero-order resonation unit 110 and the ground terminal, and the first capacitor C1 and the first inductor L1 are connected in parallel between the first port 100 and the first resonation unit 120. Herein, the resonant frequency of the first resonation unit 120 is equal to the zero-order resonant frequency of the first zero-order resonation unit 110. That is, the resonant frequency formed by the second inductor L2 and the second capacitor C2 connected in series is equal to the zero-order resonant frequency formed by the first capacitor C1 and the first inductor L1 connected in parallel.

The filtering unit 130 may be a filer such as an elliptic filter, a Chebyshev filter, and a Butterworth filter. The filtering unit 130 includes a third inductor L3 and a third capacitor C3 connected in series to a connection terminal between the first resonation unit 120 and the second resonation unit 140; and a fourth inductor L4 and a fourth capacitor C4 connected in parallel between the ground terminal and the third capacitor C3.

The second resonation unit 140 includes a fifth capacitor C5 and a fifth inductor L5 connected in series to the second port 160. The second zero-order resonation unit 150 includes a sixth capacitor C6 and a sixth inductor L6 connected between the ground terminal and a connection terminal between the second port 160 and the second resonation unit 140 (i.e., connected in parallel to the second port 160 and the second resonation unit 140). If the second resonation unit 140 is connected in parallel to the second port 160, the fifth capacitor C5 and the fifth inductor L5 are connected in series between the second zero-order resonation unit 150 and the ground terminal, and the sixth capacitor C6 and the sixth inductor L6 are connected in parallel between the second port 160 and the second resonation unit 140. Herein, the resonant frequency of the second resonation unit 140 is equal to the zero-order resonant frequency of the second zero-order resonation unit 150. That is, the resonant frequency formed by the fifth capacitor C5 and the fifth inductor L5 connected in series is equal to the zero-order resonant frequency formed by the sixth capacitor C6 and the sixth inductor L6 connected in parallel.

As described above, by the bandwidth of the first zero-order resonation unit 110 having the zero-order resonation frequency equal to the resonant frequency of the first resonation unit 120 and the second zero-order resonation unit 150 having the zero-order resonation frequency equal to the resonant frequency of the second resonation unit 140, an impedance matching operation is performed with the filter including the first resonation unit 120, the second resonation unit 140 and the filtering unit 130 in a broadband system, thereby improving the band cut-off characteristics without degrading the characteristics of the filter including the first resonation unit 120, the second resonation unit 140 and the filtering unit 130. In particular, because the resonant frequency formed by the serial inductors L2 and L5 and capacitors C2 and C5 of the first and second resonation units 120 and 140 is equal to the zero-order resonant frequency of the parallel inductors L1 and L6 and capacitors C1 and C6 of the first and second zero-order resonation units 110 and 150, the band-pass characteristics appear without a disconnection of a band gap with the center of a zero-order resonant frequency (i.e., there is no band gap).

Specifically, the inductors L2, L3, L4 and L5 and the capacitors C2, C3, C4 and C5 included in the first resonation unit 120, the second resonation unit 140 and the filtering unit 130 is a three-order elliptic filter, a Chebyshev filter, or a Butterworth filter. The inductors L1 and L2 and the capacitors C1 and C2 of the first zero-order resonation unit 110 and the first resonation unit 120 are a balanced Composite Right/Left-Banded (CRLH) unit cell, and the inductors L5 and L5 and the capacitors C5 and C6 of the second zero-order resonation unit 160 and the second resonation unit 140 are a balanced CRLH unit cell. The first resonation unit 120/the second resonation unit 140 and the first zero-order resonation unit 110/the second zero-order resonation unit 160 and are symmetrical with respect to the filtering unit 130. The first resonation unit 120 and the second resonation unit 140 may have the same inductance and capacitance (i.e., L2=L5, and C2=C5), and the first zero-order resonation unit 110 and the second zero-order resonation unit 150 may have the same inductance and capacitance (i.e., L1=L6, and C1=C6).

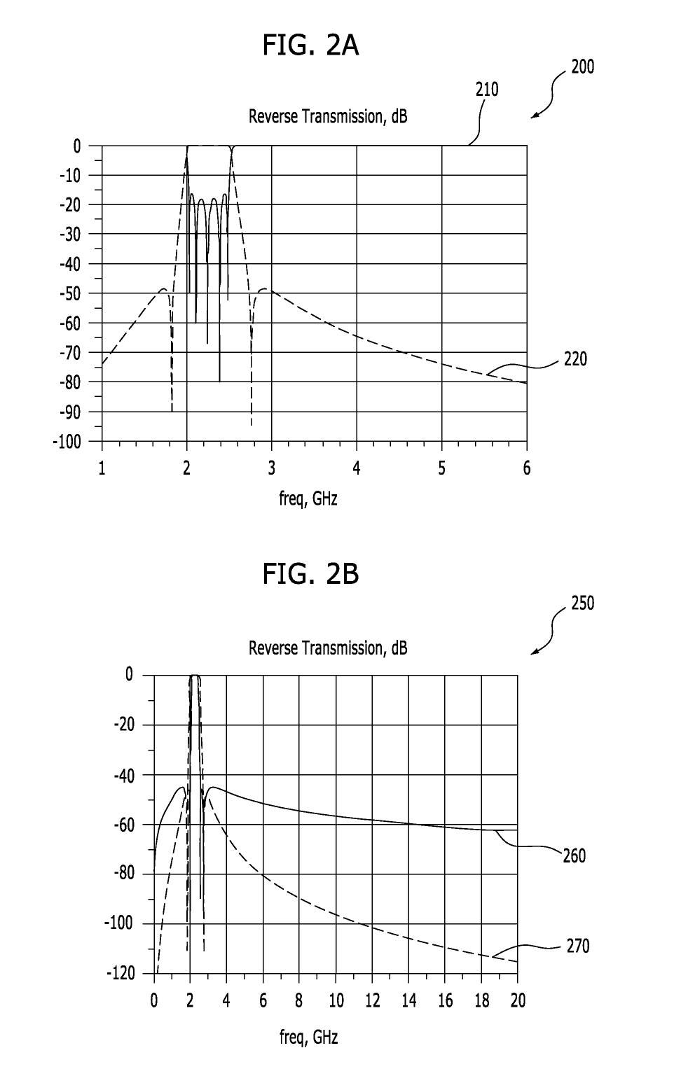

Because the resonant frequency of the first resonation unit 120 and the second resonation unit 140 is equal to the zero-order resonant frequency of the first zero-order resonation unit 110 and the second zero-order resonation unit 160, that is, because the resonant frequency formed by the inductor L2, the capacitor C2, the inductor L5 and the capacitor C5 of the balanced CRLH is equal to the zero-order resonant frequency formed by the inductor L1, the capacitor C1, the inductor L6 and the capacitor C6, it has band-pass characteristics without a band gap that appear in unbalanced conditions. Also, the band-pass center frequency of the zero-order resonation units 110 and 160 is equal to the band-pass center frequency of the filter (e.g., a third elliptic filter, a Chebyshev filter, or a Butterworth filter) including the resonation units 120 and 140 and the filtering unit 130, and the bandwidth according to the cut-off frequency of the balanced CRLH unit cell is adapted to the bandwidth of the third elliptic filter, the Chebyshev filter or the Butterworth filter to couple the CRLH cells to the filters, thereby improving the filtering spectrum characteristics of the filters. Hereinafter, an improvement in the performance of a filter in accordance with an exemplary embodiment of the present invention will be described in detail with reference to FIGS. 2A to 7B.

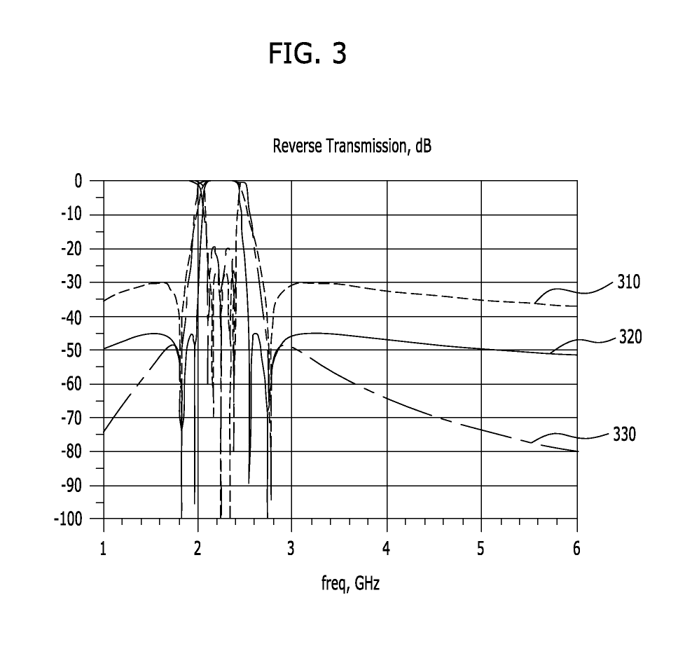

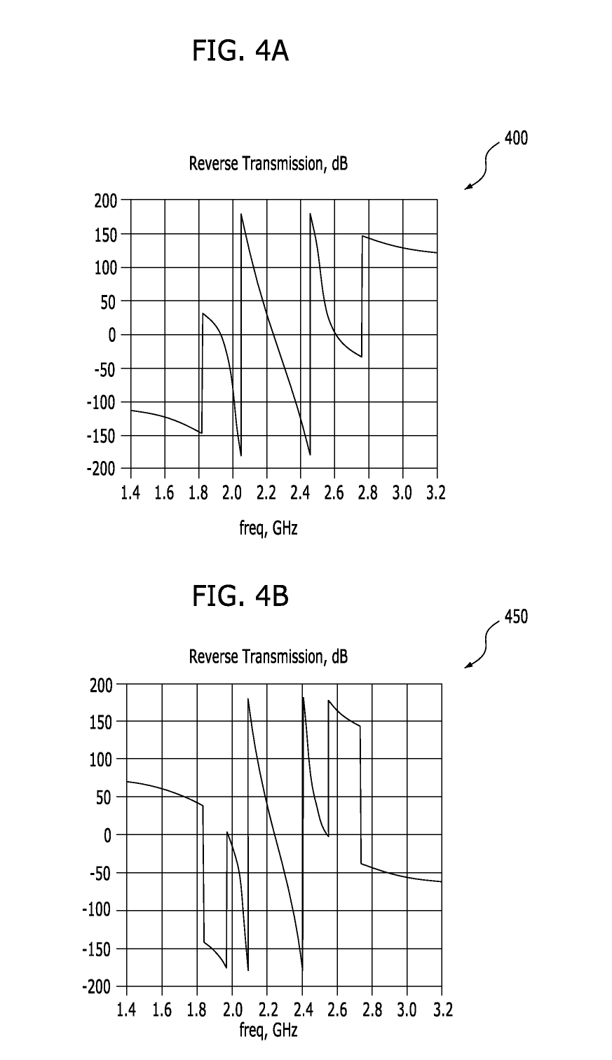

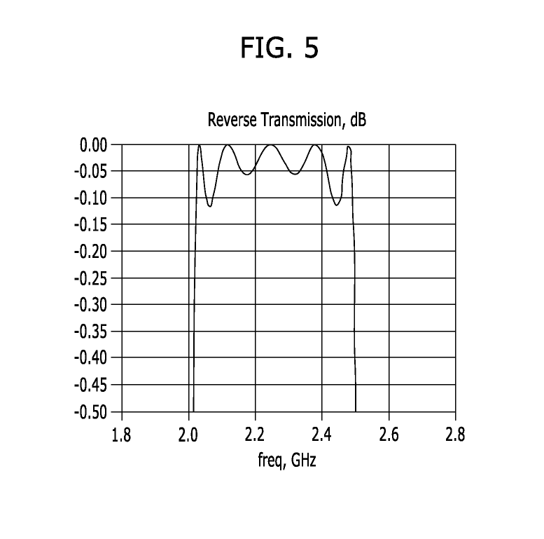

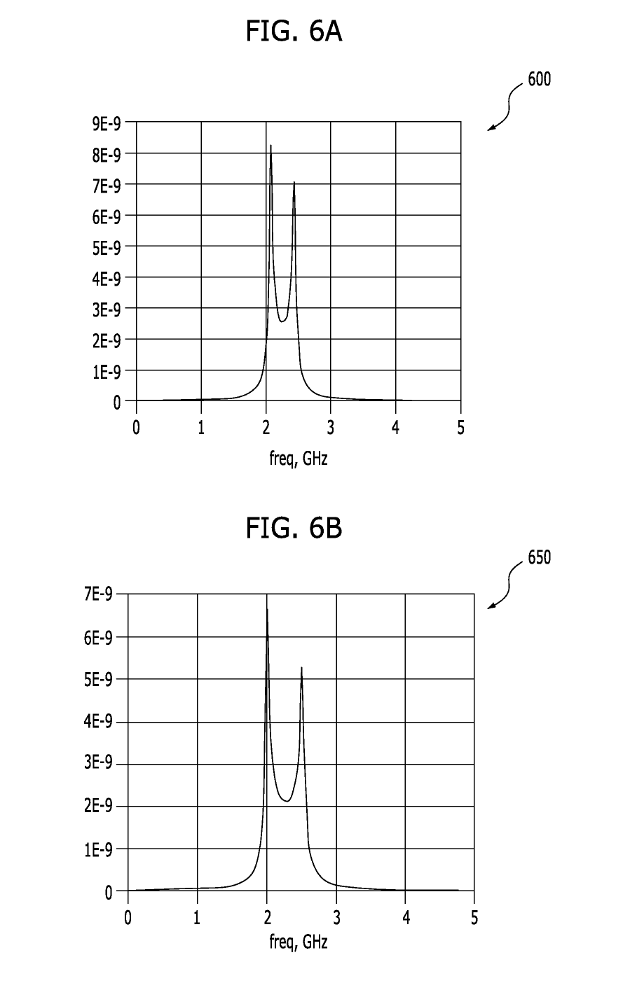

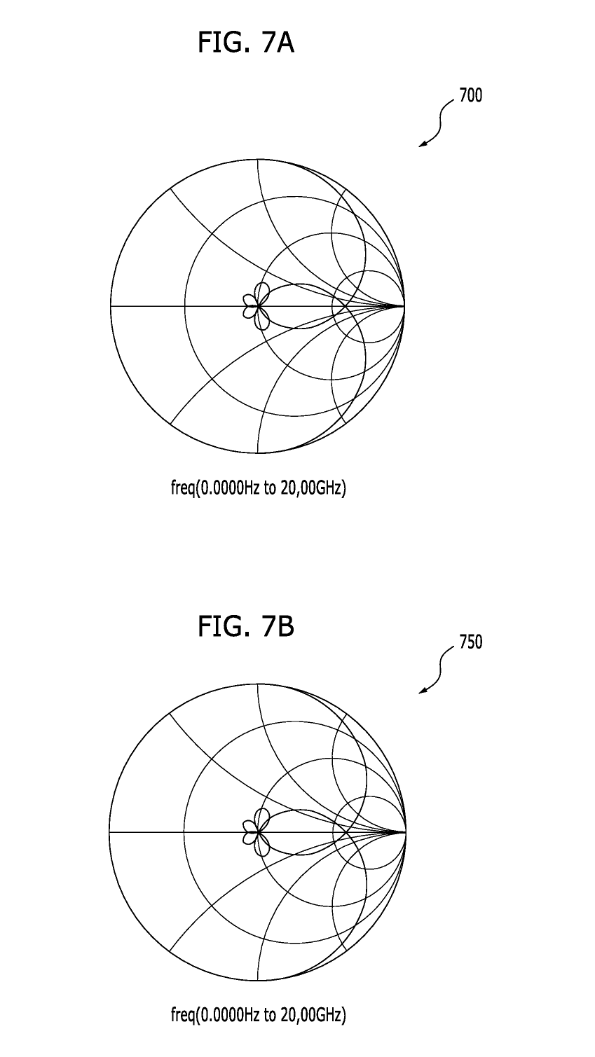

FIGS. 2A to 7B are graphs illustrating the characteristics of a filter for a communication system in accordance with an exemplary embodiment of the present invention. FIGS. 2A and 2B are graphs illustrating the band-pass characteristics of a filter in accordance with an exemplary embodiment of the present invention. FIG. 3 is a graph illustrating the transmission characteristics of a filter in accordance with an exemplary embodiment of the present invention. FIGS. 4A and 4B are graphs illustrating the phase characteristics of a filter in accordance with an exemplary embodiment of the present invention. FIG. 5 is a graph illustrating the ripple characteristics of a filter in accordance with an exemplary embodiment of the present invention. FIGS. 6A and 6B are graphs illustrating a group delay of a filter in accordance with an exemplary embodiment of the present invention. FIGS. 7A and 7B are graphs illustrating a reflection coefficient of a filter in accordance with an exemplary embodiment of the present invention.

Referring to FIGS. 2A to 7B, in accordance with an exemplary embodiment of the present invention, an elliptic filter coupled with the zero-order resonation units 110 and 150 (hereinafter referred to as a first filter) has a larger pass band than an elliptic filter that has an S11 210 and an S21 220 that are not coupled with the zero-order resonation units 110 and 150 in a narrow band 200 (hereinafter referred to as a second filter). In particular, in the band cut-off of a broad band 250, the slope of a band-pass graph 270 of the first filter decreases more rapidly than the slope of a band-pass graph 260 of the second filter. That is, unlike the second filter, the band cut-off performance of the first filter improves as the cut-off band becomes more distant.

For the band-pass characteristics (i.e., the transmission characteristics) of the first filter, because the slope of a band cut-off characteristic graph 330 changes more rapidly than the slope of a band cut-off characteristic graph 310 of the three-order second filter and the slope of a band cut-off characteristic graph 320 of the five-order second filter, it can be seen that the first filter has better band cut-off characteristics than the second filter.

When compared to the phase change characteristics 450 of the second filter, the phase change characteristics 400 of the first filter has no significant difference in the phase change depending on the frequency of a pass band. Due to the addition of a transmission zero, a phase change in the cut-off region of the second filter is large, but a phase change in the cut-off region of the first filter is small.

As illustrated in FIG. 5, in the case of the ripple characteristics of the first filter, the zero-order resonant frequency formed by the parallel inductors L1 and L6 and capacitors C1 and C6 included in the zero-order resonation units 110 and 150 is equal to the resonant frequency formed by the serial inductors L2 and L5 and capacitors C2 and C5 included in the resonation units 120 and 140 by the balanced conditions. Like the first filter with the zero-order resonation units 110 and 150 coupled to the second filter, the CRLH unit cell having the bandwidth including the bandwidth of the second filter is coupled, thereby minimizing the occurrence of a severe ripple around a cut-off region in a pass band. Accordingly, it is possible to couple the zero-order resonation units 110 and 150 to the second filter.

Like the group delay characteristics 600 of the second filter, the group delay characteristics 650 of the first filter is about 6 to 8 nsec and there is no characteristic degradation in the second filter. The reflection coefficient of the first filter (i.e., an input reflection coefficient 700 and an output reflection coefficient 750) is similar to the reflection coefficient of the second filter, and there is no characteristic degradation in the second filter. The first filter and the second filter in accordance with an exemplary embodiment of the present invention improve the filtering performance without degrading the RF spectrum characteristics.

As described above, the present invention performs an impedance matching operation in a broadband communication system by using a zero-order resonator with a zero-order resonant frequency equal to a resonant frequency thereof, thereby making it possible to improve the filtering performance of a filter without RF spectrum degradation. Also, the present invention couples a zero-order resonator with a filter (e.g., an elliptic filter, a Chebyshev filter, and a Butterworth filter), thereby making it possible to improve the filtering performance (e.g., the band rejection characteristics) by controlling the bandwidth of the filter.

While the present invention has been described with respect to the specific embodiments, it will be apparent to those skilled in the art that various changes and modifications may be made without departing from the spirit and scope of the invention as defined in the following claims.

What is claimed is:

1. A resonator for a communication system, comprising:
a first zero-order resonation unit connected in parallel to an input terminal of a filter and having a zero-order resonant frequency equal to a resonant frequency of a first resonation unit of the filter connected in series to the input terminal; and
a second zero-order resonation unit connected in parallel to an output terminal of the filter and having a zero-order resonant frequency equal to a resonant frequency of a second resonation unit of the filter connected in series to the output terminal;
wherein the first zero-order resonation unit includes a first inductor and a first capacitor connected in parallel between a ground terminal and a connection terminal between the input terminal and the first resonation unit;
wherein the second zero-order resonation unit includes a second inductor and a second capacitor connected in parallel between the ground terminal and a connection terminal between the output terminal and the second resonation unit.

2. The resonator of claim 1, wherein the zero-order resonant frequency formed by the first inductor and the first capacitor is equal to the resonant frequency of the first resonation unit; and the zero-order resonant frequency formed by the second inductor and the second capacitor is equal to the resonant frequency of the second resonation unit.

3. The resonator of claim 1, wherein the first resonation unit includes a third inductor and a third capacitor connected in series to the input terminal; and the second resonation unit includes a fourth capacitor and a fourth inductor connected in series to the output terminal.

4. The resonator of claim 3, wherein the first inductor and the third inductor and the first capacitor and the third capacitor are a balanced Composite Right/Left-Handed (CRLH) unit cell; and the second inductor and the fourth inductor and the second capacitor and the fourth capacitor are a balanced CRLH unit cell.

5. The resonator of claim 1, wherein the filter includes a filtering unit connected between the first resonation unit and the second resonation unit; and the first zero-order resonation unit/the second zero-order resonation unit and the first resonation unit/the second resonation unit are symmetrical with respect to the filtering unit.

6. A filter for a communication system, comprising:
a first resonation unit connected in an input terminal and having a first resonant frequency;
a filtering unit connected in series to the first resonation unit to filter a signal inputted through the input terminal;
a second resonation unit connected in between the filtering unit and an output terminal and having a second resonant frequency;
a first zero-order resonation unit connected in a connection terminal between the input terminal and the first resonation unit and having a first zero-order resonant frequency equal to the first resonant frequency; and
a second zero-order resonation unit connected in a connection terminal between the output terminal and the second resonation unit and having a second zero-order resonant frequency equal to the second resonant frequency;
wherein the first zero-order resonation unit includes a first inductor and a first capacitor connected in parallel between a ground terminal and the connection terminal between the input terminal and the first resonation unit;
wherein the second zero-order resonation unit includes a second inductor and a second capacitor connected in parallel between the ground terminal and the connection terminal between the output terminal and the second resonation unit;
wherein the first resonation unit includes a third inductor and a third capacitor connected in series to the input terminal;
wherein the second resonation unit includes a fourth capacitor and a fourth inductor connected in series to the output terminal.

7. The filter of claim 6, wherein the first inductor and the third inductor and the first capacitor and the third capacitor are a balanced Composite Right/Left-Handed (CRLH) unit cell; and the second inductor and the fourth inductor and the second capacitor and the fourth capacitor are a balanced CRLH unit cell.

8. The filter of claim 6, wherein the first zero-order resonant frequency formed by the first inductor and the first capacitor is equal to the first resonant frequency formed by the third inductor and the third capacitor; and the second zero-order resonant frequency formed by the second inductor and the second capacitor is equal to the second resonant frequency formed by the fourth inductor and the fourth capacitor.

9. The filter of claim 6, wherein the first zero-order resonation unit/the second zero-order resonation unit and the first resonation unit/the second resonation unit are symmetrical with respect to the filtering unit.

10. The filter of claim 6, wherein the first resonation unit connected in series to the input terminal, the second resonation unit connected in series between the filtering unit and the output terminal, the first zero-order resonation unit connected in parallel to the connection terminal between the input terminal and the first resonation unit, and the second zero-order resonation unit connected in parallel to the connection terminal between the output terminal and the second resonation unit.

11. The filter of claim 10, wherein the filtering unit includes:
a fifth inductor and a fifth capacitor connected in series between the ground terminal and a connection terminal between the first resonation unit and the second resonation unit; and
a sixth inductor and a sixth capacitor connected in parallel between the ground terminal and the fifth capacitor.

12. A resonator for a communication system, comprising:
a first zero-order resonation unit connected in series to an input terminal of a filter and having a zero-order resonant frequency equal to a resonant frequency of a first resonation unit of the filter connected in parallel to the input terminal; and
a second zero-order resonation unit connected in series to an output terminal of the filter and having a zero-order resonant frequency equal to a resonant frequency of a second resonation unit of the filter connected in parallel to the output terminal;
wherein the first zero-order resonation unit includes a first inductor and a first capacitor connected in parallel between the input terminal and the first resonation unit;
wherein the second zero-order resonation unit includes a second inductor and a second capacitor connected in parallel between the output terminal and the second resonation unit.

13. The resonator of claim 11, wherein the zero-order resonant frequency formed by the first inductor and the first capacitor is equal to the resonant frequency of the first resonation unit; and the zero-order resonant frequency formed by the second inductor and the second capacitor is equal to the resonant frequency of the second resonation unit.

14. The resonator of claim 12, wherein the first resonation unit includes a third inductor and a third capacitor connected in series between the input terminal and a ground terminal; and the second resonation unit includes a fourth capacitor and a fourth inductor connected in series between the output terminal and the ground terminal.

15. The resonator of claim 13, wherein the first inductor and the third inductor and the first capacitor and the third capacitor are a balanced Composite Right/Left-Handed (CRLH) unit cell; and the second inductor and the fourth inductor and the second capacitor and the fourth capacitor are a balanced CRLH unit cell.

16. The resonator of claim 11, wherein the filter includes a filtering unit connected between the first resonation unit and the second resonation unit; and the first zero-order resonation unit/the second zero-order resonation unit and the first resonation unit/the second resonation unit are symmetrical with respect to the filtering unit.

17. The filter of claim 6, wherein the first resonation unit connected in parallel to the input terminal, the second resonation unit connected in parallel between the filtering unit and the output terminal, the first zero-order resonation unit connected in series between the input terminal and the first resonation unit, and the second zero-order resonation unit connected in series between the output terminal and the second resonation unit.

18. The filter of claim 17, wherein the filtering unit includes:
a fifth inductor and a fifth capacitor connected in series between the ground terminal and a connection terminal between the first resonation unit and the second resonation unit; and
a sixth inductor and a sixth capacitor connected in parallel between the ground terminal and the fifth capacitor.
